(19) United States
(12) Patent Application Publication
(10) Pub. No.: US 2025/0391450 A1
(43) Pub. Date: Dec. 25, 2025

(54) Circuits And Methods For Systolic Memory

(71) Applicant: Altera Corporation, San Jose, CA (US)

(72) Inventor: Peter McLean, Brampton (CA)

(73) Assignee: Altera Corporation, San Jose, CA (US)

(21) Appl. No.: 19/307,479

(22) Filed: Aug. 22, 2025

(51) Int. Cl. G11C 7/10

(52) U.S. Cl. CPC G11C 7/1066; G11C 7/1069; G11C 7/1096

(57) ABSTRACT

A systolic array circuit includes memory circuits, storage circuits, and processing elements. Each of the memory circuits accesses first read data and second read data in response to a read address. The systolic array circuit is coupled to provide the first read data accessed from each of the memory circuits to a first one or more of the processing elements. The systolic array circuit is coupled to provide the second read data accessed from each of the memory circuits through one of the storage circuits to a second one or more of the processing elements.

### BACKGROUND

Configurable logic integrated circuits can be configured by users to implement desired custom logic functions. In a typical scenario, a logic designer uses computer-aided design tools to design a custom logic circuit. When the design process is complete, the computer-aided design tools generate configuration data. The configuration data is then loaded into configuration memory elements that configure configurable logic circuits in the integrated circuit to perform the functions of the custom logic circuit. Configurable logic integrated circuits can be used for co-processing in big-data or fast-data applications. For example, configurable logic integrated circuits may be used in application acceleration tasks in a datacenter and may be reprogrammed during datacenter operation to perform different tasks.

### BRIEF DESCRIPTION OF DRAWINGS

FIG. 1 is a diagram that illustrates an example of a systolic array circuit for performing read operations from a systolic memory circuit.

FIG. 2 is a diagram that illustrates an additional example of a systolic array circuit for performing read operations from a systolic memory circuit.

FIG. 3 is a diagram that illustrates an example of a two dimensional (2D) systolic array circuit that includes two systolic memory circuits that are coupled to an array of processing elements (PEs).

FIG. 4 illustrates an example of a systolic array circuit that includes write circuitry for write operations to a systolic memory circuit.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

A systolic array circuit supplies data according to a schedule to one or more downstream circuits. The one or more downstream circuits can be any circuits that use delayed data from a memory source (e.g., random access memory or RAM). Examples of the downstream circuits include data processing elements (also referred to herein as processing elements or PEs), circuits that perform batch processing of computations, and vector processors with systolic delayed control sets. The PEs may be symmetric and uniform or may be non-uniform and non-symmetric PEs that perform different functions. Each of the circuits independently computes a partial result of a computation as a function of the data received from one or more of its upstream circuits neighbors, stores the partial result, and then provides the partial result downstream as an output to one or more additional circuits neighbors or as a final result in the case of the last circuit in a systolic array circuit. The computation can, as examples, include multiply and accumulate, convolution, matrix multiplication, correlation, parallel integration, or data sorting.

When creating systolic array circuits in configurable integrated circuits (ICs), such as field programmable gate arrays (FPGAs), memories typically supply data to one or more dimensions of the systolic array circuits. These memories can, for example, be distributed into block random access memories (RAMs) or lookup table (LUT) based memories in an FPGA. Systolic array circuits have data that is supplied to different stages of the systolic array circuit at different time steps. For example, a one-dimensional systolic vector can supply a single scalar on one axis that propagates throughout the stages of the systolic vector. On the other axis, a parallel operand is delivered to each stage in the axis at the corresponding time step to meet the single scalar.

The organization and wiring of RAMs to deliver delayed data to the stages of the systolic vectors and systolic array circuits impacts placement, area, routing, and the number of random access memory (RAM) primitives that are used for a systolic array circuit. Artificial intelligence (AI) inference on an FPGA typically make use of systolic array circuits with multiple dimensions and many stages. The convolution or matrix multiplication computations for AI inference are unrolled into regular patterns delayed by a systolic array circuit across an IC.

According to some examples disclosed herein, a systolic array circuit includes first registers coupled in series, memory circuits (such as RAMs) coupled to the first registers, downstream circuits coupled in series, and second registers coupled between the memory circuits and the downstream circuits. The first registers store a read address that is provided to the memory circuits. The memory circuits access read data stored at the read address received from the first registers. The memory circuits provide the read data to the downstream circuits. The downstream circuits process the read data. Each of the downstream circuits generates a partial result of a computation using the read data. The partial result is provided as an input to one or more of the next downstream circuits.

Each of the first registers provides the read address to one of the memory circuits. Each of the memory circuits accesses read data bits stored in that memory circuit in response to the read address. Each of the memory circuits provides a first subset of the read data bits to a first one or more of the downstream circuits and a second subset of the read data bits to a second one or more of the downstream circuits that is next to the first one or more of the downstream circuits. One of the second registers delays the second subset of the read data bits so that the second subset of the read data bits and a third subset of read data bits accessed from a different one of the memory circuits are received by the second one or more of the downstream circuits at the same time. This technique can optimize the use of memory circuits to provide a more efficient use of resources in an integrated circuit (IC) and to improve placement and timing characteristics for AI applications that use systolic array circuits.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

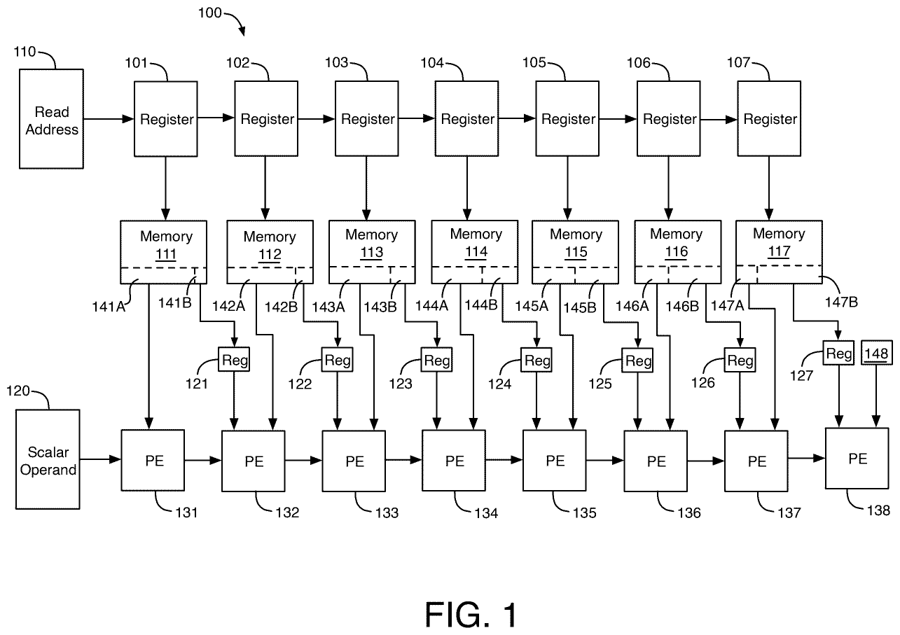

FIG. 1 is a diagram that illustrates an example of a systolic array circuit 100 for performing read operations from a systolic memory circuit. Systolic array circuit 100 includes register circuits 101-107, memory circuits 111-117, registers circuits 121-127, and processing elements 131-138 (PEs) or other types of downstream circuits, as described above. The PEs disclosed herein can be any types of processing circuits, such as digital signal processing circuits or vector processors. The memory circuits 111-117 function as the systolic memory circuit. Although 7 registers circuits 101-107, 7 memory circuits 111-117, 7 register circuits 121-127, and 8 PEs 131-138 are shown in FIG. 1, systolic array circuit 100 can have any number of registers, memory circuits, and PEs. According to various examples, the register circuits disclosed herein can be replaced with any other suitable type of sequential storage circuits.

Memory circuits 111-117 can be, as an example, random access memories (RAMs), such as RAM primitives. Register circuits 101-107 are coupled together in series (e.g., as a shift register) as shown in Figure (FIG. 1 and clocked by a clock signal (not shown). Systolic array circuit 100 and the other systolic array circuits disclosed herein can be made in any type of integrated circuit (IC), such as a configurable IC (e.g., a field programmable gate array (FPGA) or programmable logic device (PLD)), a microprocessor IC, a graphics processing unit (GPU) IC, a central processing unit (CPU), a memory IC, an application specific IC, a transceiver IC, etc.

The PEs 131-138 are coupled together in series to form a chain of PEs. A scalar operand 120 is provided to the first PE 131. PE 131 generates a partial result of a computation using the scalar operand 120 and read data bits accessed from memory circuit 111. The partial result generated by PE 131 is provided to the PE 132. PE 132 generates a partial result of a computation using the partial result generated by PE 131 and read data bits accessed from memory circuits 111 and 112. The partial result generated by PE 132 is provided to the PE 133. PE 133 generates a partial result of a computation using the partial result generated by PE 132 and read data bits accessed from memory circuits 112 and 113. Each of the additional PEs 134-138 generates a partial result of a computation using the partial result generated by a previous PE in the chain of PEs and using read data bits received from two different ones of the memory circuits 113-117 and an additional memory circuit not shown in FIG. 1. Further details of the operation of systolic array circuit 100 are described below.

A read address 110 is provided to and stored in register circuit 101. The read address 110 is then provided to and stored in each subsequent register circuit 102-107, as shown by the arrows between register circuits 101-107 in FIG. 1. The read address stored in each of the register circuits 101-107 is provided to a respective one of the memory circuits 111-117, as shown by the arrows in FIG. 1. Each of the memory circuits 111-117 accesses read data bits that are stored in that memory circuit at the read address received from the respective one of the register circuits 101-107. Each of the memory circuits 111-117 provides the read data bits that are accessed at the read address to two of the PEs 131-138, as shown by the arrows in FIG. 1.

Each of the memory circuits 111-117 accesses more read data bits at the read address than are needed by the respective PE to process the partial result, as shown by the dotted lines in each of the memory circuits 111-117 in FIG. 1. In the example of FIG. 1, each of the memory circuits 111-117 provides read data bits to two of the PEs 131-138. According to a specific example, each of the memory circuits 111-117 can store more read data bits than are used by each respective PE, because each of memory circuits 111-117 may have a fixed data bit width (e.g., 10, 20, or 40) that corresponds to the number of read data bits. The bit width of scalar operand 120 for the PEs (or a multiple thereof) may not match the fixed data bit width of memory circuits 111-117.

Each of the register circuits 121-127 delays a second subset of the read data bits accessed from one of the memory circuits 111-117 so that this second subset of the read data bits arrives at one of the PEs concurrently with the first subset of the read data bits accessed from the next adjacent one of the memory circuits 111-117. As a specific example, memory circuit 111 provides a first subset 141A of the read data bits accessed at the read address received from register circuit 101 to PE 131. PE 131 generates a partial result of a computation using the scalar operand 120 and the first subset 141A of the read data bits accessed from memory circuit 111. The partial result generated by PE 131 is provided to the PE 132.

Memory circuit 111 provides a second subset 141B of the read data bits accessed at the read address received from register circuit 101 to register circuit 121. Register circuit 121 stores the second subset 141B of the read data bits accessed from memory circuit 111 in response to a clock signal and then provides the second subset 141B of the read data bits to PE 132. As a result, PE 132 receives the second subset 141B of the read data bits a delay after the PE 131 receives the first subset 141A of the read data bits. Memory circuit 112 provides a first subset 142A of the read data bits accessed at the read address received from register circuit 102 to PE 132. Register circuit 121 functions to delay the second subset 141B of the read data bits (e.g., by one or more clock cycles) so that the second subset 141B of the read data bits arrives at PE 132 concurrently with the first subset 142A of the read data bits accessed from memory circuit 112. The delay provided by the register circuit 121 to the second subset 141B of the read data bits may equal or approximately equal the delay that register circuit 102 provides to the read address. PE 132 generates a partial result of a computation using the partial result generated by PE 131, the second subset 141B of the read data bits accessed from memory circuit 111, and the first subset 142A of the read data bits accessed from memory circuit 112. The partial result generated by PE 132 is provided to the PE 133.

As another example, memory circuit 112 provides a second subset 142B of the read data bits accessed at the read address received from register circuit 102 to register circuit 122. Register circuit 122 stores the second subset 142B of the read data bits accessed from memory circuit 112 in response to a clock signal and then provides the second subset 142B of the read data bits to PE 133. As a result, PE 133 receives the second subset 142B of the read data bits a delay after the PE 132 receives the first subset 142A of the read data bits. Memory circuit 113 provides a first subset 143A of the read data bits accessed at the read address received from register circuit 103 to PE 133. Register circuit 122 functions to delay the second subset 142B of the read data bits (e.g., by one or more clock cycles) so that the second subset 142B of the read data bits arrives at PE 133 concurrently with the first subset 143A of the read data bits accessed from memory circuit 113. The delay provided by the register circuit 122 to the second subset 142B of the read data bits may equal or approximately equal the delay that register circuit 103 provides to the read address. PE 133 generates a partial result of a computation using the partial result generated by PE 132, the second subset 142B of the read data bits accessed from memory circuit 112, and the first subset 143A of the read data bits accessed from memory circuit 113. The partial result generated by PE 133 is provided to the PE 134.

First subsets 144A, 145A, 146A, and 147A of the read data bits accessed from memory circuits 114-117 at the read address received from register circuits 104-107 are provided to PEs 134-137, respectively. Second subsets 143B, 144B, 145B, 146B, and 147B of the read data bits accessed from memory circuits 113-117 at the read address received from register circuits 103-107 are provided to PEs 134-138, respectively. Register circuits 123, 124, 125, 126, and 127 delay the second subsets 143B, 144B, 145B, 146B, and 147B of the read data bits, respectively, so that the second subsets 143B, 144B, 145B, 146B, and 147B of the read data bits are received at the PEs 134-138 concurrently with the first subsets 144A, 145A, 146A, 147A, and 148 of the read data bits, respectively. Read data bits 148 are accessed from an additional memory circuit (not shown) and provided to PE 138.

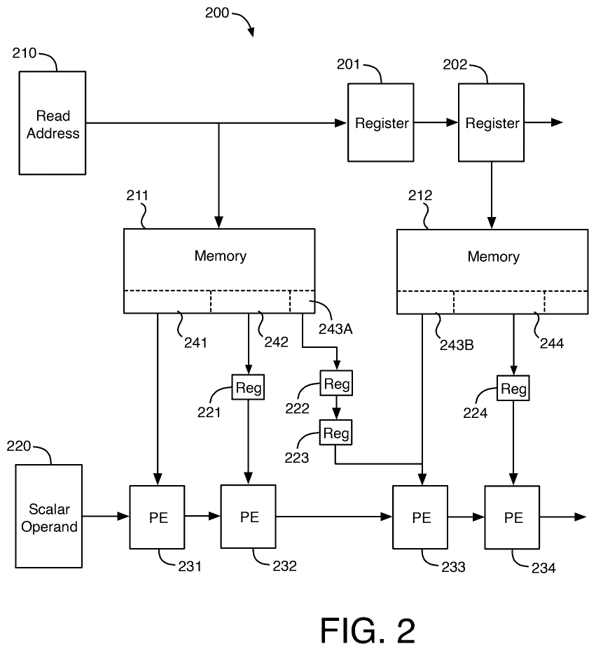

FIG. 2 is a diagram that illustrates an additional example of a systolic array circuit 200 for performing read operations from a systolic memory circuit. Systolic array circuit 200 includes register circuits 201-202, memory circuits 211-212, registers circuits 221-224, and processing elements (PEs) 231-234. Although 2 register circuits 201-202, 2 memory circuits 211-212, 4 registers circuits 221-224, and 4 PEs are shown in FIG. 2, systolic array circuit 200 can have any number of registers, memory circuits, and PEs. Memory circuits 211-212 can be, as an example, random access memory (RAM), such as RAM primitives. The memory circuits 211-212 function as a systolic memory circuit.

In the example of FIG. 2, 2 register circuits delay a read address 210 between each adjacent pair of the memory circuits. For example, registers 201-202 are coupled in series (e.g., as a shift register) as shown in Figure (FIG. 2 and clocked by a clock signal (not shown) to delay the read address 210 provided to the memory circuit 212. As a result, the memory circuit 212 receives the read address 210 delayed by the delays added by the register circuits 201-202 relative to when the memory circuit 211 receives the read address 210.

Memory circuits 211-212 access data words stored in memory circuits 211-212, respectively, at the read address 210 (or portions thereof). The data words accessed from memory circuits 211-212 are provided to the PEs 231-234 for processing. Each of the memory circuits 211-212 accesses two or more data words at the read address 210. Each of the PEs 231-234 processes only one data word accessed from the memory circuits to generate a partial result of a computation. Data words are shown by the dotted lines in each of the memory circuits 211-212. In the example of FIG. 2, each of the memory circuits 211-212 provides data bits to three of the PEs.

A first data word 241 is accessed from memory circuit 211 at the read address 210 and is then provided to PE 231. PE 231 generates a partial result of a computation using scalar operand 220 and the first data word 241 accessed from memory circuit 211. The partial result generated by PE 231 is provided to PE 232.

A second data word 242 is accessed from memory circuit 211 at the read address 210 and then is provided to register circuit 221. Register circuit 221 stores the second data word 242 accessed from memory circuit 211 in response to a clock signal and then provides the second data word 242 to PE 232. PE 232 generates a partial result of a computation using the partial result generated by PE 231 and the second data word 242 accessed from memory circuit 211. The partial result generated by PE 232 is provided to PE 233.

A first subset 243A of the bits in a third data word are accessed from memory circuit 211 at the read address 210 and are then provided to register circuit 222. Register circuit 222 stores the first subset 243A of the bits in the third data word accessed from memory circuit 211 in response to a clock signal and then provides the first subset 243A of the bits in the third data word to register circuit 223. Register circuit 223 stores the first subset 243A of the bits in the third data word accessed from memory circuit 211 in response to a clock signal and then provides the first subset 243A of the bits in the third data word to PE 233.

A second subset 243B of the bits in the third data word are accessed from memory circuit 212 at the read address 210 received from register circuit 202 and are then provided to PE 233. Register circuits 222-223 function to delay the first subset 243A of the bits in the third data word (e.g., by two or more clock cycles) so that the first subset 243A of the bits in the third data word arrive at PE 233 concurrently with the second subset 243B of the bits in the third data word accessed from memory circuit 212. The delay provided by the register circuits 222-223 to the first subset 243A of the bits in the third data word may equal or approximately equal the total delay that register circuits 201-202 provide to the read address 210.

PE 233 generates a partial result of a computation using the partial result generated by PE 232, the first subset 243A of the bits in the third data word received from register circuit 223, and the second subset 243B of the bits in the third data word accessed from memory circuit 212. The partial result generated by PE 233 is provided to PE 234.

A fourth data word 244 is accessed from memory circuit 212 at the read address 210 and is then provided to register circuit 224. Register circuit 224 stores the fourth data word 244 accessed from memory circuit 212 in response to a clock signal and then provides the fourth data word 244 to PE 234. PE 234 receives the fourth data word 244 after the fourth data word 244 has been delayed by the register circuit 224. PE 234 generates a partial result of a computation using the partial result generated by PE 233 and the fourth data word 244 accessed from memory circuit 212.

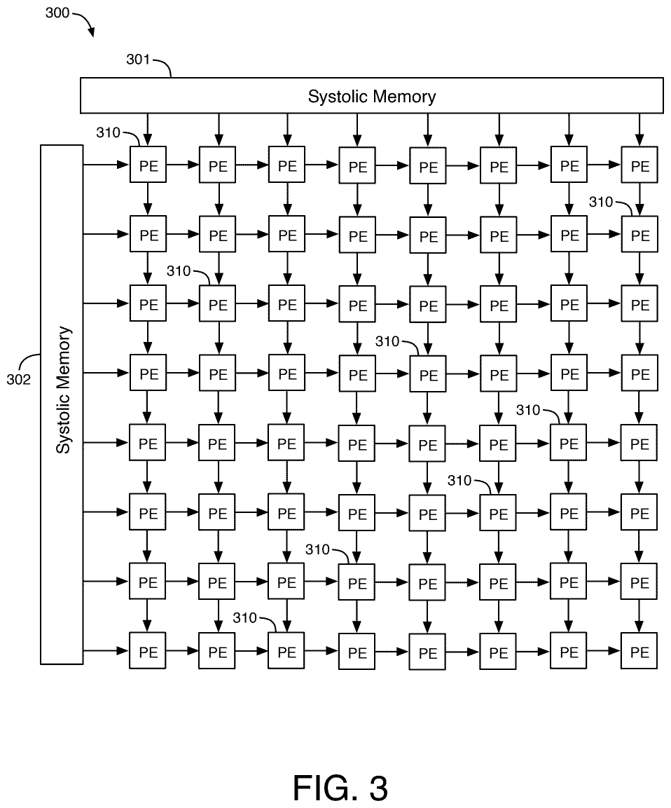

FIG. 3 is a diagram that illustrates an example of a two dimensional (2D) systolic array circuit 300 that includes two systolic memory circuits 301 and 302 that are coupled to an array of 64 processing elements (PEs) 310. Although 64 PEs 310 are shown in FIG. 3, a systolic array circuit with two systolic memory circuits can have any number of PEs. Systolic memory circuit 301 accesses data bits at a read address and provides the data bits to a first row of the PEs. Systolic memory circuit 302 accesses data bits at a read address and provides the data bits to a first columns of the PEs. The systolic memory circuits disclosed herein with respect to FIGS. 1 and 2 are examples of each of the systolic memory circuits 301 and 302. The systolic memory circuits 301 and 302 are coupled to register circuits for delaying the read address and the read data bits, as disclosed herein with respect to FIG. 1 or 2.

Each of the PEs 310 generates one or more partial results of a computation using two inputs and provides the one or more partial results to two additional PEs 310, as shown by the arrows in FIG. 3. The PEs 310 in the first top row receive data bits as an input from systolic memory circuit 301. The PEs 310 in the first left column receive data bits as an input from systolic memory circuit 302. Data propagates through the PEs 310 in wave-like manner from the upper left corner of the systolic array circuit 300 to the lower right corner of the systolic array circuit 300, in the diagram of FIG. 3.

An N-dimensional systolic array can have one, N, or more systolic RAMs, where N is any positive integer greater than 1. Thus, systolic arrays can have 2, 3, or more dimensions. As other examples, each PE in a systolic array can contain a smaller systolic array, vector, or DSP chain to form nested systolic arrays or vectors.

The systolic memory circuits disclosed herein can be implemented in a configurable integrated circuit (IC), such as an FPGA or PLD, using software that can configure configurable memory circuits in the IC for depth, stage width, and multidimensional number of stages. In a configurable IC, configurable memory circuits can be configured as systolic memory circuits to perform smart quantization of the depth and stage widths to RAM primitives, instantiate registers on the read address, write address, and write data to match the stage delay of a particular RAM primitive, and instantiate registers to delay the read data bits that are part of extra quantization bits provided to neighboring PEs.

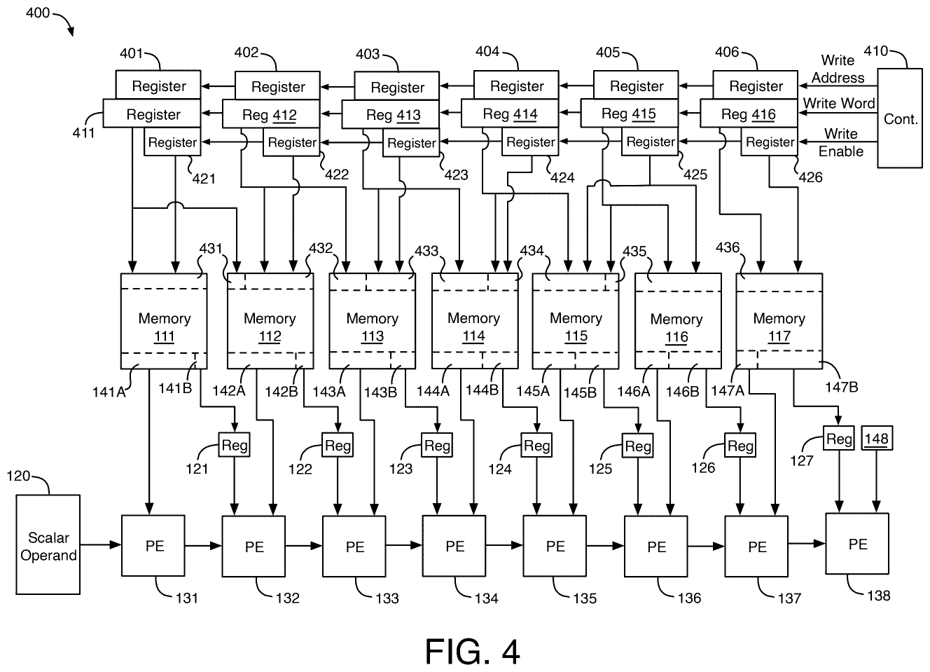

FIG. 4 illustrates an example of a systolic array circuit 400 that includes write circuitry for write operations to a systolic memory circuit. The write operations of the systolic array circuit 400 are more flexible for different design approaches, because the write operations do not have the same scheduling requirements as the read circuitry shown in FIGS. 1 and 2. To avoid operations where corrupt or incomplete write data is read, high-level control prevents intersection of read and write operations. Because the total read data bits of the systolic memory circuits are often much larger than most memory interfaces, the write data word is narrower than the total read data bits in the systolic memory circuit. Additionally, the written word bits may not be an even multiple or factor of the individual read word bits. Also, the write circuitry minimizes the fanout to distributed memories in the IC (e.g., in an FPGA fabric) to improve placement and routing.

Systolic array circuit 400 includes register (reg.) circuits 401-406, 411-416, 421-426, and 121-127. Systolic array circuit 400 also includes controller circuit 410 (e.g., a counter circuit), memory circuits 111-117, and PEs 131-138. The number of registers circuits, memory circuits, and PEs shown in FIG. 4 are merely examples. Systolic array circuit 400 can have any suitable number of registers, memory circuits, and PEs. Memory circuits 111-117 can be, as an example, random access memories (RAMs), such as RAM primitives in a systolic memory circuit.

During a write operation to memory circuits 111-117, the controller circuit 410 provides a write address, 6 write data words, and a write enable value to register circuits 401-406, 411-416, and 421-426, respectively. The write address is shifted into the 6 register circuits 401-406. A first write data word is shifted through register circuits 412-416 into register circuit 411. A second write data word is shifted through register circuits 413-416 into register circuit 412. A third write data word is shifted through register circuits 414-416 into register circuit 413. A fourth write data word is shifted through register circuits 415-416 into register circuit 414. A fifth write data word is shifted through register circuit 416 into register circuit 415. A sixth write data word is shifted into register circuit 416. The write enable value is shifted into each of the register circuits 421-426.

The register circuits 401-406, 411-416, and 421-426 are controlled by multiple clock-enable signals. In each step of the write operation, the incoming step number or sub-address of the write address is examined, and then a determination is made as to whether the write data word is meant to be stored in a downstream register circuit 411-415 or if the write data word is meant to remain stored in the register circuit 411-416 that write data word is currently stored in. If the write data word is meant to be stored in a downstream register circuit, then the write data word is forwarded to the next register circuit 411-415. If the write data word is meant to remain in the register circuit 411-416 that write data word is currently stored in, then the corresponding one of the register circuits 421-426, respectively, activates its write enable output signal.

After six write data words are stored in register circuits 411-416, the write address is stored in register circuits 401-406, and the write enable value is stored in register circuits 421-426, the write data words, the write address, and the write enable value are provided to the memory circuits 111-117. Each of the memory circuits 111-117 has a write enable input that is controlled by the write enable value received from the register circuit 421-426 corresponding to the right-most write step in FIG. 4 that sends write data words to that memory circuit, as described in further detail below.

A first subset of bits in the first data word 431 are stored in memory circuit 111 at the write address received from register circuit 401 in response to a write enable value (signal) received from register circuit 421. A second subset of bits in the first data word 431 are stored in memory circuit 112 at the write address received from register circuit 401 in response to a write enable value received from register circuit 422.

A first subset of bits in the second data word 432 are stored in memory circuit 112 at the write address received from register circuit 402 in response to the write enable value received from register circuit 422. A second subset of bits in the second data word 432 are stored in memory circuit 113 at the write address received from register circuit 402 in response to a write enable value received from register circuit 423.

A first subset of bits in the third data word 433 are stored in memory circuit 113 at the write address received from register circuit 403 in response to the write enable value received from register circuit 423. A second subset of the bits in the third data word 433 are stored in memory circuit 114 at the write address received from register circuit 403 in response to a write enable value received from register circuit 424.

A first subset of bits in the fourth data word 434 are stored in memory circuit 114 at the write address received from register circuit 404 in response to the write enable value received from register circuit 424. A second subset of bits in the fourth data word 434 are stored in memory circuit 115 at the write address received from register circuit 404 in response to a write enable value received from register circuit 425.

A first subset of bits in the fifth data word 435 are stored in memory circuit 115 at the write address received from register circuit 405 in response to the write enable value received from register circuit 425. A second subset of bits in the fifth data word 435 are stored in memory circuit 116 at the write address received from register circuit 405 in response to the write enable value received from register circuit 425. The sixth data word 436 is stored in memory circuit 117 at the write address received from register circuit 406 in response to a write enable value received from register circuit 426.

The read operations for reading data from the memory circuits 111-117 and providing the read data through register circuits 121-127 and the conductors shown by arrows in FIG. 4 to PEs 131-138 operates as disclosed herein with respect to FIG. 1, which is described above.

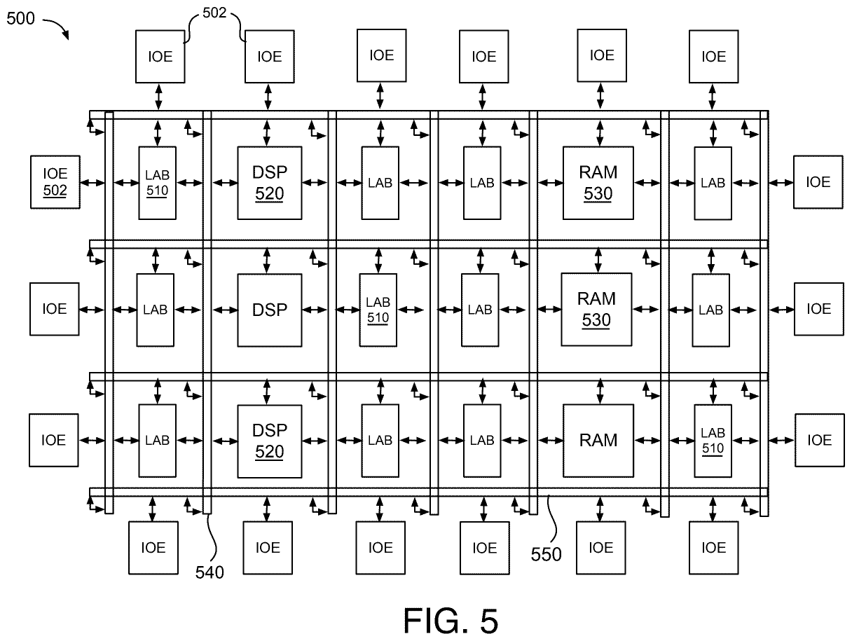

FIG. 5 illustrates an example of a configurable logic integrated circuit (IC) 500 that can include, for example, any of the circuitry disclosed herein with respect to any, some, or all of FIGS. 1, 2, 3, and/or 4. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

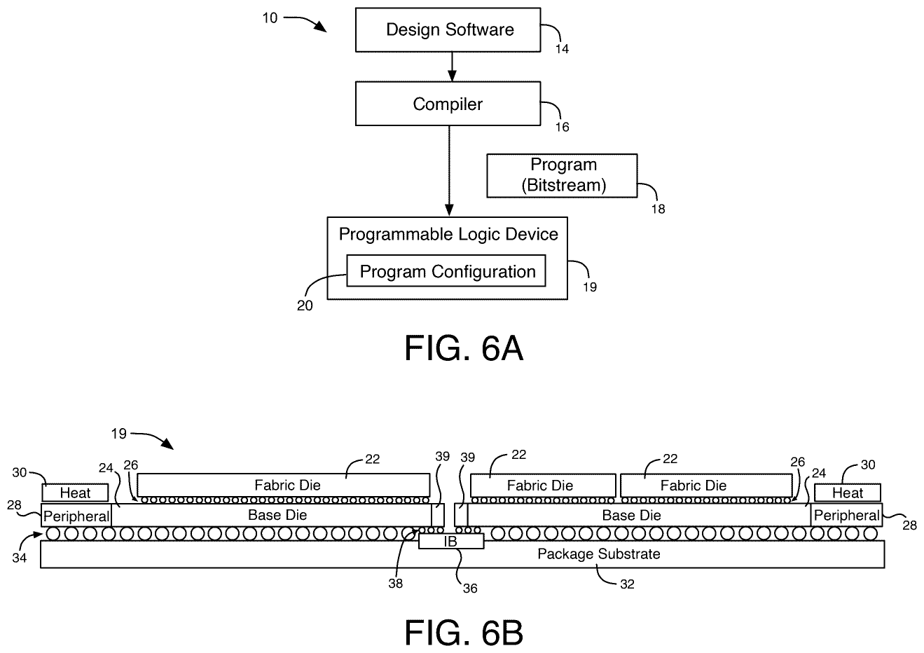

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

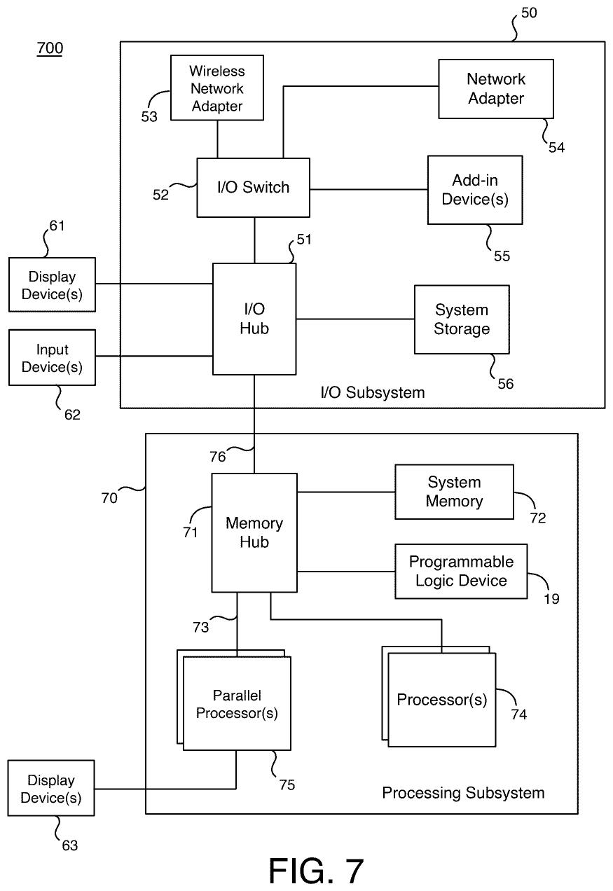

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are not described. Example 1 is a systolic array circuit comprising: memory circuits; first storage circuits; and downstream circuits, wherein each of the memory circuits accesses first read data and second read data in response to a read address, wherein the systolic array circuit is coupled to provide the first read data accessed from each of the memory circuits to at least a first one of the downstream circuits, and wherein the systolic array circuit is coupled to provide the second read data accessed from each of the memory circuits through one of the first storage circuits to at least a second one of the downstream circuits.

In Example 2, the systolic array circuit of Example 1, wherein the memory circuits function as a systolic memory.

In Example 3, the systolic array circuit of any one of Examples 1-2 further comprises: second storage circuits coupled in series to delay the read address and to provide at least a portion of the read address to each of the memory circuits.

In Example 4, the systolic array circuit of Example 3, wherein a first delay provided by each of the second storage circuits to the read address matches a second delay provided by a corresponding one of the first storage circuits to the second read data.

In Example 5, the systolic array circuit of any one of Examples 1-4, wherein each of the first storage circuits delays the second read data received from a first one of the memory circuits to cause the second read data received from the first one of the memory circuits to arrive at the second one of the downstream circuits concurrently with the first read data accessed from a second one of the memory circuits.

In Example 6, the systolic array circuit of any one of Examples 1-5, wherein each of the downstream circuits in a subset of the downstream circuits computes a partial result of a computation using the second read data received from a first one of the memory circuits and the first read data received from a second one of the memory circuits.

In Example 7, the systolic array circuit of any one of Examples 1-6, wherein each of the downstream circuits in a subset of the downstream circuits computes a partial result of a computation using an output of another one of the downstream circuits.

In Example 8, the systolic array circuit of any one of Examples 1-7 further comprises: second storage circuits, wherein the systolic array circuit is coupled to provide the second read data accessed from each of the memory circuits through one of the first storage circuits and through one of the second storage circuits to the second one of the downstream circuits.

In Example 9, the systolic array circuit of any one of Examples 1-8, wherein the downstream circuits are coupled together in a two dimensional array, and wherein each of the downstream circuits in a subset of the downstream circuits generates a partial result of a computation using two inputs and provides the partial result to at least an additional one of the downstream circuits.

Example 10 is a method for processing using processing circuits in a systolic array circuit, the method comprising: accessing data bits stored in memory circuits in response to a read address; providing a first subset of the data bits accessed from each of the memory circuits to a first one or more of the processing circuits; providing a second subset of the data bits accessed from each of the memory circuits to one of first register circuits; providing the second subset of the data bits accessed from each of the memory circuits from the one of the first register circuits to a second one or more of the processing circuits; and performing a computation at each of the processing circuits in a first subset of the processing circuits using the second subset of the data bits received from a first one of the memory circuits and the first subset of the data bits received from a second one of the memory circuits.

In Example 11, the method of Example 10 further comprises: storing the read address in second register circuits that are coupled in series; and providing at least a portion of the read address from each of the second register circuits to one of the memory circuits.

In Example 12, the method of any one of Examples 10-11 further comprises: delaying the second subset of the data bits output by the first one of the memory circuits at the one of the first register circuits to cause the second subset of the data bits output by the first one of the memory circuits to arrive at the second one or more of the processing circuits concurrently with the first subset of the data bits output by the second one of the memory circuits.

In Example 13, the method of any one of Examples 10-12, wherein providing the second subset of the data bits accessed from each of the memory circuits from the one of the first register circuits to the second one or more of the processing circuits further comprises: providing the second subset of the data bits accessed from each of the memory circuits to one of second register circuits; and providing the second subset of the data bits from each one of the second register circuits to one or more of the processing circuits.

In Example 14, the method of any one of Examples 10-13 further comprises: providing an output generated by each of the processing circuits in a second subset of the processing circuits to two additional ones of the processing circuits, wherein the processing circuits are coupled in a two dimensional array.

Example 15 is an integrated circuit comprising: first register circuits coupled to store a write address; second register circuits coupled to store write data bits; third register circuits coupled to store a write enable value; and memory circuits that function as a systolic memory, wherein each of the second register circuits in at least a subset of the second register circuits provides a first subset of the write data bits for storage in a first one of the memory circuits and a second subset of the write data bits for storage in a second one of the memory circuits.

In Example 16, the integrated circuit of Example 15 further comprises: processing elements, wherein each of the processing elements in a subset of the processing elements computes a partial result of a computation using first read data read from the first one of the memory circuits and second read data read from the second one of the memory circuits.

In Example 17, the integrated circuit of any one of Examples 15-16, wherein each of the memory circuits stores the write data bits received from one of the second register circuits at a portion of the write address received from one of the first register circuits in response to the write enable value received from one of the third register circuits.

In Example 18, the integrated circuit of any one of Examples 15-17, wherein each of the memory circuits stores the write data bits received from one of the second register circuits in response to the write enable value received from one of the third register circuits that corresponds to the second subset of the write data bits.

In Example 19, the integrated circuit of any one of Examples 15-18 further comprises: a controller circuit that provides the write address to the first register circuits, the write data bits to the second register circuits, and the write enable value to the third register circuits.

In Example 20, the integrated circuit of any one of Examples 15-19, wherein each of the memory circuits in a subset of the memory circuits stores the second subset of the write data bits received from a first one of the second register circuits and the first subset of the write data bits received from a second one of the second register circuits.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A systolic array circuit comprising:
memory circuits;
first storage circuits; and
downstream circuits, wherein each of the memory circuits accesses first read data and second read data in response to a read address, wherein the systolic array circuit is coupled to provide the first read data accessed from each of the memory circuits to at least a first one of the downstream circuits, and wherein the systolic array circuit is coupled to provide the second read data accessed from each of the memory circuits through one of the first storage circuits to at least a second one of the downstream circuits.

2. The systolic array circuit of claim 1, wherein the memory circuits function as a systolic memory.

3. The systolic array circuit of claim 1 further comprising:
second storage circuits coupled in series to delay the read address and to provide at least a portion of the read address to each of the memory circuits.

4. The systolic array circuit of claim 3, wherein a first delay provided by each of the second storage circuits to the read address matches a second delay provided by a corresponding one of the first storage circuits to the second read data.

5. The systolic array circuit of claim 1, wherein each of the first storage circuits delays the second read data received from a first one of the memory circuits to cause the second read data received from the first one of the memory circuits to arrive at the second one of the downstream circuits concurrently with the first read data accessed from a second one of the memory circuits.

6. The systolic array circuit of claim 1, wherein each of the downstream circuits in a subset of the downstream circuits computes a partial result of a computation using the second read data received from a first one of the memory circuits and the first read data received from a second one of the memory circuits.

7. The systolic array circuit of claim 1, wherein each of the downstream circuits in a subset of the downstream circuits computes a partial result of a computation using an output of another one of the downstream circuits.

8. The systolic array circuit of claim 1 further comprising:
second storage circuits, wherein the systolic array circuit is coupled to provide the second read data accessed from each of the memory circuits through one of the first storage circuits and through one of the second storage circuits to the second one of the downstream circuits.

9. The systolic array circuit of claim 1, wherein the downstream circuits are coupled together in a two dimensional array, and wherein each of the downstream circuits in a subset of the downstream circuits generates a partial result of a computation using two inputs and provides the partial result to at least an additional one of the downstream circuits.

10. A method for processing using processing circuits in a systolic array circuit, the method comprising:
accessing data bits stored in memory circuits in response to a read address;
providing a first subset of the data bits accessed from each of the memory circuits to a first one or more of the processing circuits;
providing a second subset of the data bits accessed from each of the memory circuits to one of first register circuits;
providing the second subset of the data bits accessed from each of the memory circuits from the one of the first register circuits to a second one or more of the processing circuits; and
performing a computation at each of the processing circuits in a first subset of the processing circuits using the second subset of the data bits received from a first one of the memory circuits and the first subset of the data bits received from a second one of the memory circuits.

11. The method of claim 10 further comprising:
storing the read address in second register circuits that are coupled in series; and
providing at least a portion of the read address from each of the second register circuits to one of the memory circuits.

12. The method of claim 10 further comprising:
delaying the second subset of the data bits output by the first one of the memory circuits at the one of the first register circuits to cause the second subset of the data bits output by the first one of the memory circuits to arrive at the second one or more of the processing circuits concurrently with the first subset of the data bits output by the second one of the memory circuits.

13. The method of claim 10, wherein providing the second subset of the data bits accessed from each of the memory circuits from the one of the first register circuits to the second one or more of the processing circuits further comprises:
providing the second subset of the data bits accessed from each of the memory circuits to one of second register circuits; and
providing the second subset of the data bits from each one of the second register circuits to one or more of the processing circuits.

14. The method of claim 10 further comprising:
providing an output generated by each of the processing circuits in a second subset of the processing circuits to two additional ones of the processing circuits, wherein the processing circuits are coupled in a two dimensional array.

15. An integrated circuit comprising:
first register circuits coupled to store a write address;
second register circuits coupled to store write data bits;
third register circuits coupled to store a write enable value; and
memory circuits that function as a systolic memory, wherein each of the second register circuits in at least a subset of the second register circuits provides a first subset of the write data bits for storage in a first one of the memory circuits and a second subset of the write data bits for storage in a second one of the memory circuits.

16. The integrated circuit of claim 15 further comprising:
processing elements, wherein each of the processing elements in a subset of the processing elements computes a partial result of a computation using first read data read from the first one of the memory circuits and second read data read from the second one of the memory circuits.

17. The integrated circuit of claim 15, wherein each of the memory circuits stores the write data bits received from one of the second register circuits at a portion of the write address received from one of the first register circuits in response to the write enable value received from one of the third register circuits.

18. The integrated circuit of claim 15, wherein each of the memory circuits stores the write data bits received from one of the second register circuits in response to the write enable value received from one of the third register circuits that corresponds to the second subset of the write data bits.

19. The integrated circuit of claim 15 further comprising:
a controller circuit that provides the write address to the first register circuits, the write data bits to the second register circuits, and the write enable value to the third register circuits.

20. The integrated circuit of claim 15, wherein each of the memory circuits in a subset of the memory circuits stores the second subset of the write data bits received from a first one of the second register circuits and the first subset of the write data bits received from a second one of the second register circuits.
